(19) United States
(12) Patent Application Publication
(10) Pub. No.: US 2025/0021026 A1
(43) Pub. Date: Jan. 16, 2025

(54) APPARATUS FOR SUPPLYING LIQUID TARGET MATERIAL TO A RADIATION SOURCE

(71) Applicant: ASML Netherlands B.V., Veldhoven (NL)

(72) Inventors: William Peter VAN DRENT, Best (NL); Jan Steven Christiaan WESTERLAKEN, Heesch (NL); Daniel Jozef Maria DIRECKS, Simpelveld (NL); Johannes Henricus Wilhelmus JACOBS, Heeze (NL); Maurice Wilhelmus Leonardus Hendricus FEIJTS, Grevenbicht (NL); Edwin Johan BUIS, Belfeld (NL); Bart Leonardus KNAPEN, Kessenich (NL); Nicolaas Johannes Wilhelmus REUVERS, Eindhoven (NL); Bastiaan Lambertus Wilhelmus Marinus VAN DE VEN, Rosmalen (NL)

(73) Assignee: ASML Netherlands B.V., Veldhoven (NL)

(21) Appl. No.: 18/711,842

(22) PCT Filed: Nov. 18, 2022
(86) PCT No.: PCT/EP2022/082376

§ 371 Date: May 20, 2024

Related U.S. Application Data
(60) Provisional application No. 63/281,958, filed on Nov. 22, 2021.

(30) Foreign Application Priority Data
Nov. 22, 2021 (EP) 21209681.2

(51) Int. Cl. G03F 7/00; H05G 2/00

(52) U.S. Cl. CPC G03F 7/70891; G03F 7/70033; H05G 2/0023; H05G 2/008

(57) ABSTRACT

The present invention relates to an apparatus for supplying a liquid target material to a radiation source, comprising a first reservoir, a pressurizing system configured to pressurize a hydraulic fluid, and a separating device configured to separate the hydraulic fluid from the liquid target material in the first reservoir and to transfer a pressure from the hydraulic fluid to the liquid target material. The invention also relates to an associated method of supplying liquid target material to a radiation source.

### CROSS-REFERENCE TO RELATED APPLICATIONS

This application claims priority of EP application 21209681.2 which was filed on 22 Nov. 2021 and U.S. application 63/281,958 which was filed on 22 Nov. 2021 and which are incorporated herein in its entirety by reference.

### FIELD

The present invention relates to an apparatus for supplying a liquid target material to a lithographic radiation source. The present invention further relates to a fuel emitter including such an apparatus, a radiation source including such a fuel emitter, a lithographic apparatus including such a radiation source, and a method for supplying liquid target material to a lithographic radiation source.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 n.

EUV radiation is used in photolithography processes to produce extremely small features in substrates or silicon wafers. Methods to produce EUV radiation include, but are not limited to, converting a material that has an element, for example, xenon, lithium, or tin, with an emission line in the EUV range in a plasma state. In one such method, often termed laser produced plasma (“LPP”), the required plasma can be produced by irradiating a target material, for example, in the form of a droplet, plate, tape, stream, or cluster of material, with an amplified light beam. For this process, the plasma is typically produced in a sealed vessel, for example, a vacuum chamber, and monitored using various types of metrology equipment.

In a current state-of-the-art apparatus for supplying a tin target material, in the form of a droplet, a reservoir containing liquid tin is pressurized using Argon gas pressurized to a pressure of approximately 275 bar. The pressurized liquid tin is then transported to a nozzle configured to provide a stream of droplets of liquid tin to be irradiated by a radiation source to form a plasma.

An amount of EUV radiation produced is dependent on the amount of plasma produced per time period, which is dependent on the amount of liquid tin provided to an irradiation site to be converted into plasma by irradiation. The amount of EUV radiation can be improved by providing more liquid tin droplets per time unit. Increasing the number of droplets per second while maintaining droplet spacing requires a higher speed of the droplet stream. The stability of the EUV radiation can be improved by increasing the spacing between successive droplets. This reduces interaction between the plasma burst and the subsequent arriving next droplets. Increasing spacing between droplets also requires increasing the speed of the droplet stream. A method to increase the speed of the droplet stream is to increase the pressure acting on the liquid target material. A drawback of the current state-of-the-art apparatus for supplying the tin target material is that the pressure acting on the liquid tin cannot be increased easily to meet future higher EUV radiation level or power level demands. Another drawback may be that the liquid tin is reactive, at a relatively high temperature, and at a relatively high pressure.

US 2010/282987 A1 describes an arrangement for generating EUV radiation based on a hot plasma using liquid emitter material. An emitter material supply unit has at least a first pressure vessel and a second pressure vessel between a reservoir vessel and an injection device for generating a high emitter material pressure for an injection unit. The pressure vessels are acted upon by a high-pressure gas system with a gas pressure in the megapascal range, and the emitter material supply unit has means for switching the high-pressure gas system from one pressure vessel to the other pressure vessel and for correspondingly alternately switching the injection unit to the constant emitter material pressure of the respective pressure vessel being pressurized, wherein at least one of the pressure vessels can be refilled during the continuous operation of droplet generation and plasma generation.

### SUMMARY

Considering the above, it is an object of the invention to be able to provide higher EUV radiation levels for EUV lithography machines.

According to a first aspect of the disclosure, there is provided an apparatus for supplying a liquid target material to a radiation source. The apparatus comprises: a first reservoir; a pressurizing system configured to pressurize a hydraulic fluid, e.g. a liquid; and a separating device configured to separate the hydraulic fluid from the liquid target material in the first reservoir and to transfer a pressure from the hydraulic fluid to the liquid target material.

Advantageously, use of a hydraulic fluid instead of a gas (as may be used in prior art apparatuses) enables the liquid target material to be pressurized to an extremely high pressure that would may not be achievable when using a pressurizing gas. For example, existing apparatus may use pressurized argon gas to apply a pressure to a liquid target material in a reservoir. However, properties of argon gas change to that of a liquid-like supercritical fluid at the required extremely high pressures, and may become unpredictable. Precise regulation of compression of supercritical fluids may be complex and unpredictable, and can be avoided by use of a hydraulic fluid.

Advantageously, provision of the separating device prevents mixing of the hydraulic fluid with the liquid target material.

The separating device may comprise a deformable and/or flexible member configured to deform under the pressure from the hydraulic fluid to vary a volume in the first reservoir for the hydraulic fluid.

Advantageously, use of deformable and/or flexible member mitigates a requirement for moving parts and/or seals between components that would need to withstand high pressures, thereby reducing an amount of potential points of failure in the apparatus.

The separating device may comprises at least one of: polyimide, polytetrafluoroethylene, tungsten, tantalum, Molybdenum.

The separating device may comprises a bellows having a corrugated or concertinaed sidewall.

Advantageously, corrugated or concertinaed sidewalls may provide a predictable and controlled deformation of the separating device when a pressure is applied.

The pressurizing system may be configured to pressurize the hydraulic fluid inside the bellows or around an exterior of the bellows within the reservoir to transfer the pressure from the hydraulic fluid to the liquid target material.

That is, the bellows may deform to increase an available volume in the reservoir for one of the hydraulic fluid and the liquid target material, while simultaneously decreasing an available volume in the reservoir for the other of the hydraulic fluid and the liquid target material, and vice versa.

The pressurizing system may be configured to apply a pressure of at least 300 bar, preferably at least 700 bar, more preferably at least 900 bar, even more preferably at least 1100 bar, and most preferably at least 1300 bar, to the hydraulic fluid.

The pressurizing system may be configured to apply a pressure in the range of 300 to 2000 bar. In some examples, the pressurizing system may be configured to apply a pressure up to 1400 bar.

Advantageously, increasing the pressure acting on the liquid target material may substantially increase a speed of a droplet stream, as described above, thereby increasing an amount and a stability of EUV radiation produced in a radiation source employing the disclosed apparatus.

The apparatus may comprise at least one external heating element disposed outside a volume defined by the first reservoir and configured to controllably apply heat to the first reservoir.

Advantageously, by heating the first reservoir the liquid target material which may have a melting point substantially above an ambient temperature, may be maintained in a liquid form.

The at least one external heating element may be configured to apply heat to different regions of the first reservoir in a controlled sequence.

When heating the first reservoir to an operating temperature, the liquid target material may melt and incur a volumetric change at the transition from solid to liquid. This volumetric change may result in failure of the separating device if the system is not heated in a controlled manner, as described in more detail below.

The apparatus may comprise at least one internal heating element disposed within the volume defined by the first reservoir and configured to controllably apply heat to the volume defined by the first reservoir.

The at least one internal heating element may comprise at least one elongate heating element extending away from an inlet/outlet region of the first reservoir.

When heating the first reservoir to an operating temperature, the liquid target material may melt and incur a volumetric change at the transition from solid to liquid. This volumetric change may result in failure of the separating device when the system is not heated in a controlled manner. Provision of the at least one internal heating element may enable implementation of a liquid target material melting sequence from a supply line at the bottom of the apparatus towards a top side of the apparatus and also radially from an inside portion of the separating device towards an outside portion of the separating device.

The apparatus may comprise at least one sensor configured to sense a displacement of the separating device within the first reservoir.

The sensor may comprise a Hall-effect sensor. The sensor may comprise a magnet in combination with the Hall-effect sensor. The magnet may be coupled to the separating device and the Hall-effect sensor may sense relative movement of the magnet due to a deformation of the separating device.

The apparatus may comprise processing means coupled to the at least one sensor and configured to determine, based on a sensed displacement of the separating device a level of liquid target material in the first reservoir.

As such, an indication may be provided when the first reservoir becomes depleted of liquid target material and a refill is required.

The apparatus may comprise processing means coupled to the at least one sensor and configured to determine, based on a sensed displacement of the separating device that a displacement of the separating device has exceeded an upper or lower threshold.

Advantageously, damage to the separating device may be prevented by limiting an extent of deformation of the separating device due to an applied pressure.

The apparatus may comprise processing means coupled to the at least one sensor and configured to determine, based on a sensed displacement of the separating device, that a displacement of the separating device has deviated from an expected value.

Advantageously, a failure of the separating device may be detected. For example, a leak of hydraulic fluid to outside the apparatus or a leak of liquid target material to outside of the separating device may result in minimal or no deformation of the separating device when a pressure is applied to the hydraulic fluid. Such a static separating device or such minimal movement in the separating device may be detectable and may be indicative of a failure.

The pressurizing system may comprise a second reservoir configured for holding the hydraulic fluid and for fluid communication with the first reservoir to supply the hydraulic fluid to the first reservoir.

Advantageously, the second reservoir may be used to pressurize the hydraulic fluid, as described in more detail below.

The second reservoir may be configured as a heating chamber configured to apply heat to the hydraulic fluid.

Advantageously, a volume of the hydraulic fluid may increase as it is heated, thereby providing a controlled increased in pressure of the hydraulic fluid.

The apparatus may comprise an internal heating element disposed in a volume defined by the second reservoir and configured to be in direct contact with the hydraulic fluid held in the second reservoir.

Advantageously, by having the internal heating element in direct contact with the hydraulic fluid, a fast response may be achieved when controlling a temperature of the internal heating element to set the temperature of the hydraulic fluid.

The apparatus may comprise an external heating and/or cooling element configured to control a temperature of a sidewall of the second reservoir for heating or cooling the hydraulic fluid held in the second reservoir.

The apparatus may comprise a vessel configured for fluid communication with the second reservoir for supplying hydraulic fluid to the second reservoir.

The vessel may be disposed above the second reservoir such that gravity induces a flow of hydraulic fluid from the vessel to the second reservoir.

The vessel may act as a supply tank for supplying hydraulic fluid to the second reservoir.

The vessel may comprise a hydraulic cylinder for pre-pressurizing the hydraulic fluid.

Advantageously, the hydraulic cylinder may provide a relatively coarse control of the pressure of the hydraulic fluid in the vessel that is provided to the second reservoir, and the second reservoir may subsequently provide a relatively fine control of the pressure of the hydraulic fluid to the first reservoir, e.g. by controlling a temperature of the second reservoir.

The vessel may comprise a gas cylinder for pre-pressurizing the hydraulic fluid.

Advantageously, the gas cylinder may provide a relatively coarse control of the pressure of the hydraulic fluid in the vessel that is provided to the second reservoir, and the second reservoir may subsequently provide a relatively fine control of the pressure of the hydraulic fluid to the first reservoir, e.g. by controlling a temperature of the second reservoir.

The vessel may comprise an inlet and the pressurizing system may be configured to provide a pressurized fluid to the inlet to pre-pressurize the hydraulic fluid in the vessel.

Advantageously, provision of a pressurized fluid, e.g. a gas, to the vessel may provide a relatively coarse control of the pressure of the hydraulic fluid in the vessel that is provided to the second reservoir, and the second reservoir may subsequently provide a relatively fine control of the pressure of the hydraulic fluid to the first reservoir.

The apparatus may comprise a hydraulic fluid refreshment system. The hydraulic fluid refreshment system may comprise a drain tank configured for fluid communication with the first reservoir. The hydraulic fluid refreshment system may comprise a drain tank configured for fluid communication with the second reservoir.

The drain tank may be connected through a valve to the second reservoir. In case a rapid cooling of the second reservoir is required, hydraulic fluid from the second reservoir may be flushed towards the drain tank. Fresh hydraulic fluid may be taken from a supply tank, e.g. the vessel. In this manner, a temperature of the second reservoir can rapidly be reset.

The hydraulic fluid refreshment system may comprise a return line from the first reservoir to the drain tank. This may enable refreshment of the hydraulic fluid in case of degradation. The hydraulic fluid may be removed from the second reservoir and from the first reservoir, e.g. from within the separating device, and stored in the drain tank. Subsequently, new hydraulic fluid may be supplied from a supply tank, e.g. the vessel.

The apparatus may be provided in combination with the hydraulic fluid.

The hydraulic fluid may be selected such that, when a temperature of the hydraulic fluid and the second reservoir is increased, a volumetric expansion of the hydraulic fluid exceeds a volumetric expansion of the second reservoir.

Advantageously, a very precise control of the pressure of the hydraulic fluid may be achieved.

Advantageously, by using the expansion of hydraulic fluid in a heated second reservoir to control the pressure, ‘stick-slip’ and pressure pulses that may be associated with use of a hydraulic cylinder to generate the pressure may be avoided.

According to a second aspect of the disclosure, there is provided a fuel emitter for supplying a liquid target material to a radiation source, the system comprising a first apparatus according to the first aspect and a second apparatus according to the first aspect. The first apparatus and the second apparatus are coupled in fluid communication to an ejection system by a transport system.

The transport system may be configured to alternatingly supply liquid target material to the ejection system from the first apparatus and the second apparatus.

The transport system may be configured to equalize a pressure in the first reservoir of each of the first and the second apparatus. For example, the transport system may be configured to equalize a pressure in the first reservoir of each of the first and the second apparatus prior to and/or at the same time as, supplying liquid target material to the ejection system from both the first apparatus and the second apparatus.

The ejection system may be configured to eject a stream of droplets towards a plasma formation location of a radiation source.

The fuel emitter may comprise a droplet monitoring system configured to monitor the stream of droplets. The fuel emitter may comprise a control unit configured to adjust a pressure applied by each pressurizing system to the liquid target material in each respective reservoir based on an output of the droplet monitoring device.

According to a third aspect of the disclosure, there is provided a radiation source for a lithographic tool comprising a fuel emitter according to the second aspect, wherein the radiation source is configured to output EUV radiation.

According to a fourth aspect of the disclosure, there is provided a lithographic apparatus comprising a radiation source according to the third aspect.

According to a fifth aspect of the disclosure, there is provided a method of supplying liquid target material to a radiation source, wherein liquid target material in a first reservoir is pressurized by pressurizing a hydraulic fluid separated from the liquid target material in the first reservoir by a separating device configured to transfer a pressure from the hydraulic fluid to the liquid target material.

The liquid target material is pressurized to a pressure of at least 300 bar, preferably at least 700 bar, more preferably at least 900 bar, even more preferably at least 1100 bar, and most preferably at least 1300 bar.

A second reservoir is provided in fluid communication with the first reservoir, and the hydraulic fluid may be selected such that, when a controlled temperature of the hydraulic fluid and the second reservoir is increased, a volumetric expansion of the hydraulic fluid exceeds a volumetric expansion of the second reservoir.

The liquid target material may comprise tin.

According to a second aspect of the invention, there is provided a fuel emitter comprising an apparatus according to the first aspect and an ejection system.

According to a third aspect of the invention, there is provided a radiation source for a lithographic tool comprising a fuel emitter according to the second aspect.

According to yet another embodiment of the invention, there is provided a lithographic apparatus comprising a radiation source according to the third aspect.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 schematically depicts a radiation source according to an embodiment of the invention;

FIG. 3a schematically depicts an apparatus according to an embodiment of the invention for supplying a liquid target material to a lithographic radiation source, said apparatus being in a first situation;

FIG. 3b schematically depicts the apparatus of FIG. 3a in a second situation;

FIG. 4 schematically depicts a fuel emitter according to an embodiment of the invention;

FIG. 5 schematically depicts an apparatus according to another embodiment of the invention for supplying a liquid target material to a lithographic radiation source;

FIG. 6 schematically depicts an apparatus according to a further embodiment of the invention for supplying a liquid target material to a lithographic radiation source; and

FIG. 7 schematically depicts an apparatus according to another embodiment of the invention for supplying a liquid target material to a lithographic radiation source;

FIGS. 8a and 8b schematically depict cross-sectional views of an apparatus according to another embodiment of the invention for supplying a liquid target material to a lithographic radiation source;

FIGS. 9a and 9b schematically depict cross-sectional views of a sensor arrangement in an apparatus according to another embodiment of the invention for supplying a liquid target material to a lithographic radiation source;

FIG. 10 schematically depicts an apparatus according yet another embodiment of the invention for supplying a liquid target material to a lithographic radiation source.

### DETAILED DESCRIPTION

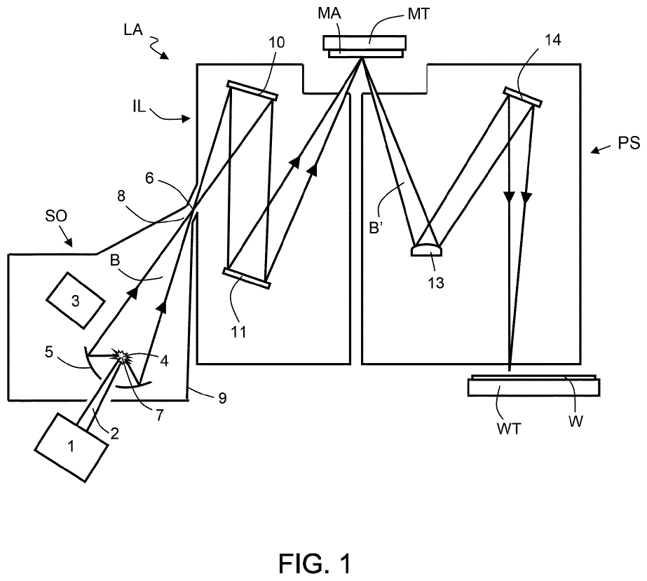

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied, or a combination of reduction factors for different directions. Although the projection system PS is illustrated as having only two mirrors 13,14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, alternatively referred to as target material, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise an ejection system configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

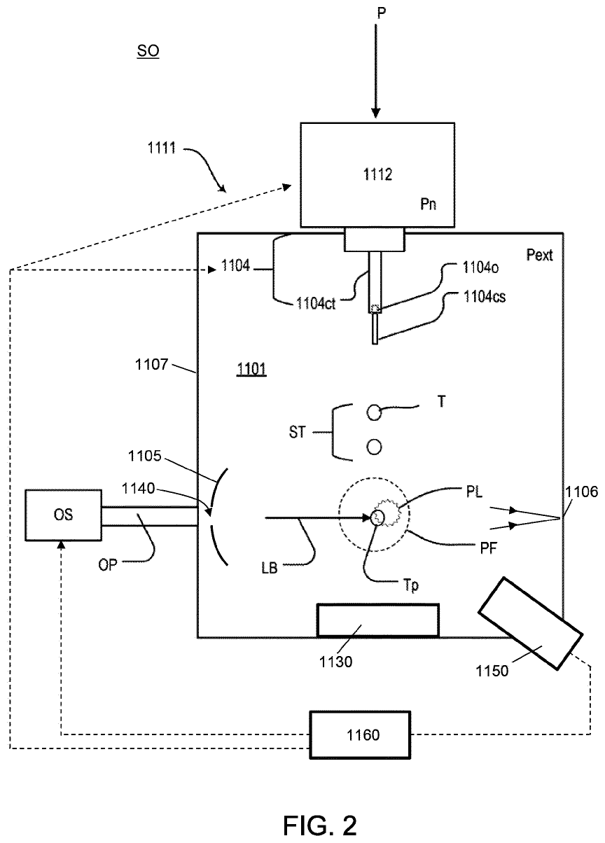

FIG. 2 schematically depicts a radiation source SO according to an embodiment of the invention that may be implemented in the lithographic apparatus LA of FIG. 1. The radiation source SO includes a fuel emitter 1111 similar to the fuel emitter 3 in FIG. 1. The fuel emitter 1111 emits a stream ST of targets T such that a target Tp is delivered to a plasma formation location PF in a low pressure hydrogen environment 1101. The target Tp includes target material. The target material is any material that emits EUV radiation when in a plasma state. For example, the target material can include water, tin, lithium, and/or xenon.

During operation, a vessel 1107 of the radiation source SO is kept under a low pressure hydrogen environment 1101 by means of a hydrogen supply system and a pump system (both not shown). The radiation source SO comprises a light source OS configured to generate a light beam LB, such as a laser beam, and to deliver the light beam LB to the low pressure hydrogen environment 1101 along an optical path OP. The light source OS may include a pulsed laser device, for example, a pulsed, gas-discharge CO2 laser device producing radiation at about 9300 nm or about 10600 nm, for example, with RF excitation, operating at a relatively high power, for example, 10 kW or higher, and high pulse repetition rate, for example, 40 kHz or more. The pulse repetition rate may be, for example, 50 kHz, 60 kHz, 70 kHz, 80 kHz, 90 kHz, 100 kHz, or more. The plasma formation location PF receives the light beam LB. An interaction between the light beam LB and the target material in the target Tp produces a plasma PL that emits EUV radiation.

The fuel emitter 1111 includes an ejection system 1104, which may include a capillary tube 1104ct that is fluidly coupled to a reservoir system 1112. The capillary tube 1104ct defines an orifice 1104o. The reservoir system 1112 contains target material under high pressure Pn. A transfer assembly may be provided between the reservoir system 1112 and the ejection system 1104. The target material is in a molten state and is able to flow, and the pressure in the low pressure hydrogen environment 1101 Pext is much lower than the pressure Pn. Thus the target material flows through the orifice 1104o. The capillary tube may be surrounded by a piezo element (not shown) that excites the target material in the tube such that an acoustic standing wave develops. The target material 102 can exit the orifice 1104o as a jet or continuous stream 1104cs of target material. The jet of target material breaks up into the individual targets T (which can be droplets). The break-up of the jet 1104cs can be controlled such that the individual droplets coalesce into larger droplets that arrive at the plasma formation location PF at a desired rate, e.g. several tens of kHz, for instance 50 kHz or more. The targets T in the stream ST can be approximately spherical, with a diameter in a range of about 15-40 micrometer, for example about 30 micrometer. The stream of targets T may be ejected from the ejection system 1104 by a combination of pressure within the reservoir system 1112 and a vibration applied to the ejection system 1104 by a piezo element (not shown).

In operation, light beam LB, which may be laser energy, is delivered in synchronism with the operation of the fuel emitter 1111, to deliver impulses of radiation to turn each droplet Tp into a plasma PL. In practice, laser energy LB may be delivered in at least two pulses: a pre-pulse with limited energy may be delivered to the droplet before it reaches the plasma formation location PF, in order to transform the target material droplet into a disk-like shape. Then a main pulse of laser energy LB may be delivered to the transformed target material at the plasma formation location PF, to generate the plasma PL. A bucket 1130 may be provided on opposite the ejection system 1104, to capture any target material that is not turned into plasma.

The radiation source SO may include a collector mirror 1105 having an aperture 1140 to allow the light beam LB to pass through and reach the plasma formation location PF. The collector mirror 1105 can be, for example, an ellipsoidal mirror that has a primary focus at the plasma formation location PF and a secondary focus at an intermediate location 1106 (also called an intermediate focus or IF) where the EUV radiation can be output from the radiation source SO and the input to, for example, a lithography tool such as the lithographic apparatus LA of FIG. 1.

The radiation source SO may further include a monitoring system 1150 to measure one or more parameters. The monitoring system 1150 may for instance include one or more target or droplet imagers that provide an output indicative of the position of a droplet, for example, relative to the plasma formation location PF, and provide this output to a master controller 1160. The master controller 1160 may then be configured to compute a droplet position and/or trajectory from which a droplet position error can be computed either on a droplet by droplet basis or on average. The monitoring system 1150 may additionally or alternatively include one or more radiation source detectors that measure one or more EUV radiation parameters, including but not limited to, pulse energy, energy distribution as a function of wavelength, energy within a particular band of wavelengths, energy outside of a particular band of wavelengths, and angular distribution of EUV intensity and/or average power.

The master controller 1160 may be configured to control the light source OS to adjust or set, for example, a light beam position, direction, shaping and/or timing in order to adjust or set the location and/or focal power of the light beam focal spot within the low pressure hydrogen environment 1101. The master controller 1160 may additionally or alternatively be configured to control the ejection system 1104 and/or the reservoir system 1112 of the fuel emitter 1111 to adjust or set, for example, a pressure Pn in the reservoir system 1112 and/or a release point of the targets T as released by the ejection system 1104 to allow the correct amount of target material to be delivered to the plasma formation location PF at the desired moment of time.

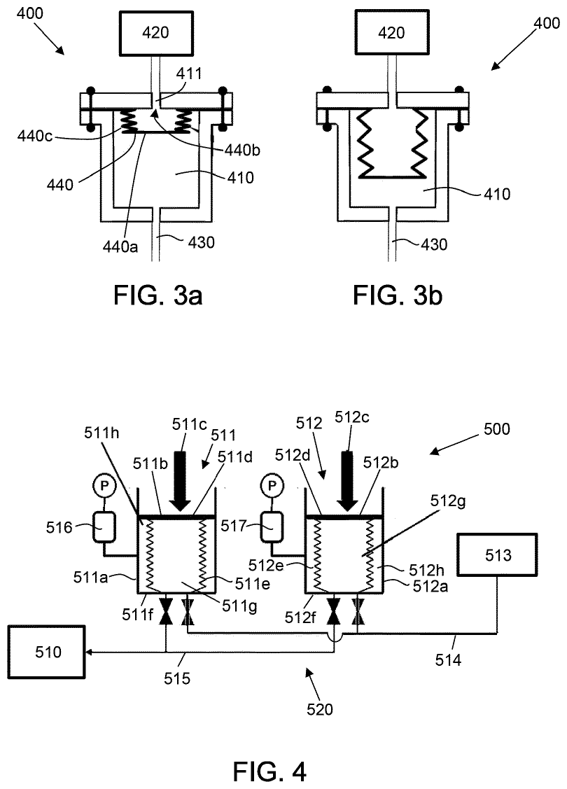

FIGS. 3a and 3b schematically depict an apparatus 400 according to an embodiment of the invention for supplying a liquid target material to a lithographic radiation source. The apparatus 400 may be the apparatus 1112 of the fuel emitter 1111 in FIG. 2.

The apparatus 400 comprises a reservoir system including a reservoir 410 configured to be connected to an ejection system via a transport system. Only a portion 430 of the transport system is visible in FIGS. 3a and 3b.

The reservoir system further comprises a pressurizing system 420 to pressurize liquid target material in the reservoir 410. The pressurizing system 420 may use any suitable hydraulic fluid, e.g. an oil, a glycol, or other liquid, to pressurize the liquid target material in the reservoir 410. The pressurizing system 420 is connected to the reservoir 410 via an inlet 411. The pressurizing system 420 further includes a separating device 440 arranged inside the reservoir 410 and surrounding the inlet 411. The separating device 440 is configured to be in contact with the liquid target material in the reservoir 410 and further configured to transfer pressure from a hydraulic fluid to the liquid target material. In this example, the separating device 440 acts as a barrier between the liquid target material and the hydraulic fluid providing more design freedom for the hydraulic fluid. The hydraulic fluid does not have to be chosen such that it can withstand the combination of temperature, pressure and reactivity of the liquid target material. The choice of hydraulic fluid can thus be made independent of the target material used as the hydraulic fluid is not in contact with the target material. This makes it easier to find suitable hydraulic fluids and configurations to increase the pressure acting on the liquid target material allowing to supply more target material to the ejection system and consequently to the plasma formation location to increase the amount of EUV radiation produced per time period.

The separating device is or includes a deformable member, in this example by implementing the separating device 440 as a bellows. The bellows 440 has a tubular shape with a closed end 440a, and open end 440b, and a deformable side wall 440c extending between the closed end 440a and the open end 440b. The deformable member, i.e. the deformable bellows 440, provides a variable interior volume of the bellows 440, and thereby a variable volume that is available in the reservoir 410 for the liquid target material.

In the embodiment of FIGS. 3a and 3b, the bellows 440 is configured to hold the hydraulic fluid inside the bellows 440. The deformable nature of the bellows 440 allows the bellows to have a first configuration in which the internal volume of the bellows 440 is relatively small and a second configuration in which the internal volume of the bellows 440 is relatively large. The situation in which the bellows 440 is in the first configuration is shown in FIG. 3a and will be referred to as the first situation. The situation in which the bellows 440 is in the second configuration is shown in FIG. 3b and will be referred to as the second situation.

Forcing hydraulic fluid in the bellows 440 using the pressurizing system 420 will cause the bellows 440 to expand and force liquid target material in the transport system 430 towards the ejection system. A benefit is that during operation the pressure inside the bellows, i.e. the pressure in the hydraulic fluid, is substantially equal to the pressure in the reservoir 410, i.e. the pressure in the liquid target material, so that the loads on the bellows can be kept relatively low allowing a relatively small wall thickness which in turn is beneficial for the deformability of the bellows. The bellows 440, i.e. the separating device 440, may comprise one or more of the following materials: polyimide, polytetrafluoroethylene, tungsten, Molybdenum and tantalum. The entire bellows 440 may be of the same material, but it is also possible that other materials are used as a core and the aforementioned materials are used as coating. The aforementioned materials may further be combined, e.g. as alloys, for example a tantalum-tungsten alloy with 2.5% tungsten.

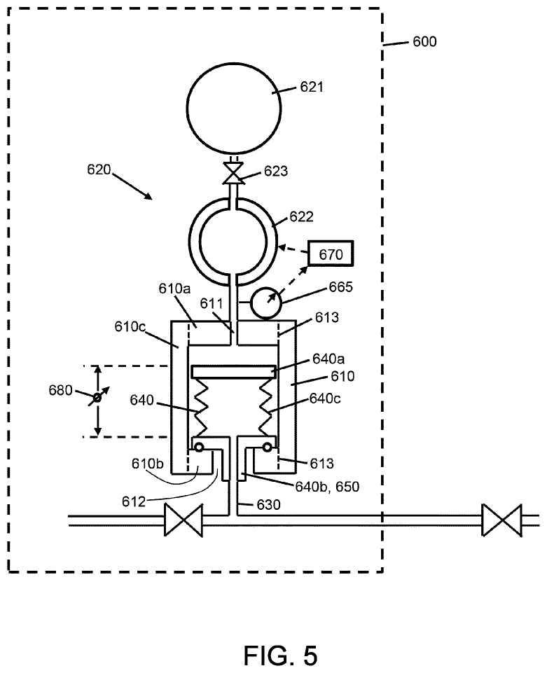

FIG. 4 schematically depicts a fuel emitter 500 according to an embodiment of the invention. The fuel emitter 500 may be the fuel emitter 1111 in FIG. 2.

The fuel emitter 500 comprises an ejection system 510 and an apparatus 520 for supplying liquid target material to the ejection system 510. The apparatus 510 comprises a first reservoir system 511, a second reservoir system 512, a priming system 513, a first transport system 514, and a second transport system 515.

The first and second reservoir systems 511, 512 are in this embodiment equal or at least similar in that they both comprise a reservoir 511a, 512a, respectively, and a pressurizing system 511b, 512b, respectively, which are configured to pressurize liquid target material in the reservoir 511a, 512, respectively. This pressurization is symbolically denoted using arrows 511c, 512c, respectively.

The pressurizing system 511b includes a piston 511d that is moveably arranged in the reservoir 511a and a bellows 511e extending between the piston 511d and an opposite bottom wall 511f of the reservoir 511a thereby dividing the space in the reservoir 511a below the piston 511d in two separated spaces indicated as a space 511g inside the bellows 511e and a space 511h outside the bellows 511e. Similarly, the pressurizing system 512b includes a piston 512d that is moveably arranged in the reservoir 512a and a bellows 512e extending between the piston 512d and an opposite bottom wall 512f of the reservoir 512a thereby dividing the space in the reservoir 512a below the piston 512d in two separated spaces indicated as a space 512g inside the bellows 512e and a space 512h outside the bellows 512e.

In this embodiment, the bellows 511e and 512e are configured to hold liquid target material, meaning that liquid target material is present in spaces 511g and 512g.

The pistons 511d and 512d form a rigid member acting as closed end of the respective bellows. The pistons 511d and 512d further close off the respective spaces 511h and 512h allowing the spaces 511h and 512h to be filled with a hydraulic fluid. Hence, the pistons 511d and 512d, i.e. the rigid members, may act as a barrier between the hydraulic fluid in respective spaces 511h and 512h and a pressure fluid provided at an opposite end of the pistons 511d and 512d, if applicable, as part of the respective pressurizing system. An advantage of the hydraulic fluid in the spaces 511h and 512h is that a counter-pressure can be applied to the bellows 511e and 512e, respectively, thereby minimizing undesired loads or deformation of the bellows 511e and 512e. When the piston is moved, the volume of the spaces 511g, 511h, 512g and 512h will increase or decrease that may result in a pressure change between the hydraulic fluid in the space 511h and 512h and respective spaces 511g and 512g. A pressure regulating system 516 for the first reservoir system 511 and a pressure regulating system 517 for the second reservoir system 512 may be provided to maintain the pressure in the hydraulic fluid substantially equal to the pressure in the liquid target material inside the respective bellows.

Pressurizing the pistons 511d, 512d may be carried out using mechanical actuators, but may also be carried out using a pressure fluid, e.g. a hydraulic fluid or a gas, provided to an opposite side of the pistons 511d, 512d, and configured to deform the respective bellows 511e, 512e.

Although not shown in FIG. 4, each pressurizing system may comprise a sensor to determine a position of the corresponding piston 511d, 512d in the respective reservoir. The position of the corresponding piston 511d, 512d can be used to control a pressure in the liquid target material, but can alternatively, or additionally, be used to determine when the reservoir is nearly empty.

Although not shown in FIG. 4, each reservoir system 511, 512 may comprise a heating system to heat the reservoir. Heat is preferably transferred by the hydraulic fluid and the bellows 511e, 512e, respectively, to the liquid target material to maintain the temperature of the liquid target material above the melting point of the target material.

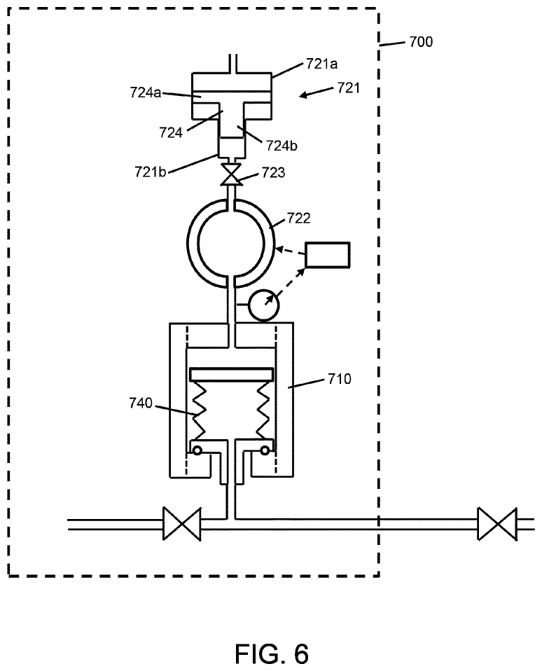

FIG. 5 schematically depicts an apparatus 600 according to another embodiment of the invention for supplying a liquid target material to a lithographic radiation source. The apparatus 600 may be the apparatus 1112 of the fuel emitter 1111 in FIG. 2.

The apparatus 600 comprises a reservoir system including a reservoir 610 configured to be connected to an ejection system via a transport system.

The reservoir system further comprises a pressurizing system 620 to pressurize liquid target material in the reservoir 610. In this embodiment, the pressurizing system 620 may use any suitable hydraulic fluid to pressurize the liquid target material in the reservoir 610. The pressurizing system 620 is connected to the reservoir 610 via an inlet 611. The pressurizing system 620 comprises a bellows 640 with a deformable member 640c which is a side wall of the bellows 640 extending between a closed end 640a and an open end 640b.

The reservoir 610 comprises a first wall portion 610a with the inlet 611, a second wall portion 610b with an opening 612, and a side wall 610c extending between the first wall portion 610a and the second wall portion 610b. In this case, both the first wall portion 610a and the second wall portion 610b are connected to the side wall 610c via a respective screw connection 613 which is beneficial in case of a relatively high pressure in the reservoir 610.

The open end 640b of the bellows 640 is in this embodiment formed by a connector part 650 to be connected to a tube 630 of the transport system. The connector part 650 is sealingly connected to the second wall portion 610b of the reservoir 610 as indicated by seal 660. An advantage of this configuration is that the bellows 640 is connected to the transport system without the content contained inside the bellows 640 being in contact with the first wall portion 610a, second wall portion 610b or the side wall 610c. In this embodiment, the liquid target material is configured to be arranged inside the bellows 640. The remainder of the volume inside the reservoir 610 is in fluid communication with the inlet 611 of the reservoir 610 and configured to be filled with the hydraulic fluid.

The pressurizing system 620 further comprises a hydraulic fluid supply 621 allowing to fill and pressurize a heating chamber 622, and preferably also acting as a release and expansion tank in case of emergency. The heating chamber 622 is in fluid communication with the inlet 611 of the reservoir 610. Filling the heating chamber 622 also involves the filling of the reservoir 610 and the tube between the heating chamber 622 and the inlet 611. Once, the pressurizing system is filled using the fluid supply 621, a valve 623 between the fluid supply 621 and the heating chamber 622 may be closed. The heating chamber 622 is used to heat the hydraulic fluid, which is preferably above the melting temperature of the target material in the bellows 640. The temperature of the hydraulic fluid in the heating chamber 622 may be used to accurately control the pressure in the pressure fluid. A pressure sensor 665 may be provided to sense a pressure of the hydraulic fluid, and a control unit 670 may be provided to control the temperature of the hydraulic fluid inside the heating chamber 622 in dependency of a measured actual pressure in the hydraulic fluid and a desired pressure in the hydraulic fluid.

As already described in relation to FIG. 4, the pressurizing system 620 may include a sensor 680 to measure a position of the closed end 640a of the bellows 640 in the reservoir 610, here relative to the open end 640b. The sensor may for instance include a magnetic member attached to the closed end of the bellows and magnetic detectors outside the reservoir to detect the position of the magnetic member. The magnetic member may also be supported from the closed end of the bellows and for instance be arranged inside or through the inlet 611 allowing a smaller distance between magnetic member and magnetic detectors as the wall thickness of the reservoir may be relatively large. Alternatively, or additionally, the sensor may include an acoustic emitter for emitting acoustic waves, and an acoustic receiver for receiving acoustic waves emitted by the acoustic emitter and reflected of a surface that is part of or connected to the closed end 640a of the bellows 640 allowing to determine a position of the closed end 640a. The acoustic emitter and receiver may be integrated to form a single component.

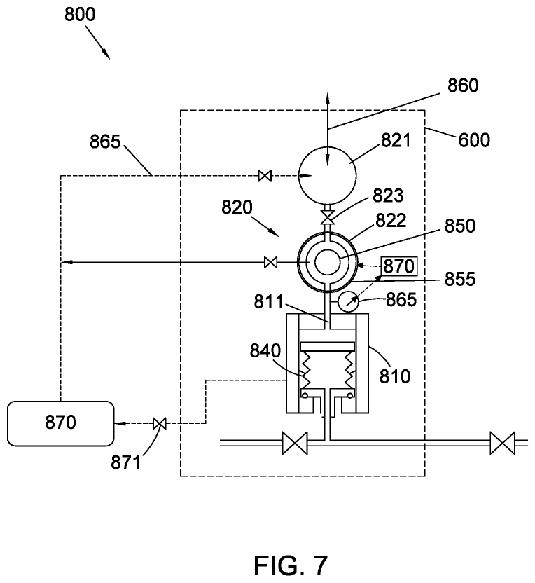

FIG. 6 schematically depicts an apparatus 700 according to another embodiment of the invention for supplying a liquid target material to a lithographic radiation source. The apparatus 700 may be the apparatus 1112 of the fuel emitter 1111 in FIG. 2.

The apparatus 700 is similar to the apparatus 600 of FIG. 5. The difference is in the pressurizing system. Emphasis in the description below is on these differences to avoid unduly repetition of the other features of the apparatus 700.

A heating chamber 722 is connected to a hydraulic cylinder 721 via a valve 723, which hydraulic cylinder 721 acts a fluid supply for the heating chamber 722.

The hydraulic cylinder 721 has a housing with a first housing portion 721a and a second housing portion 721b, and a piston 724 with a first piston portion 724a moveable in the first housing portion 721a and a second piston portion 724b moveable in the second housing portion 721b. The first piston portion 724a (and thus also the first housing portion 721a) has a cross-sectional area that is larger than the cross-sectional area of the second piston portion 724b (and thus also the second housing portion 721b). An advantage is that a pressure fluid acting on the first piston portion 724a may be at a lower pressure than a pressure as desired in the hydraulic fluid to be supplied to the heating chamber 722. The piston 724 is thus able to convert a relatively low pressure to a relatively high pressure. The pressure fluid may for instance be a gas.

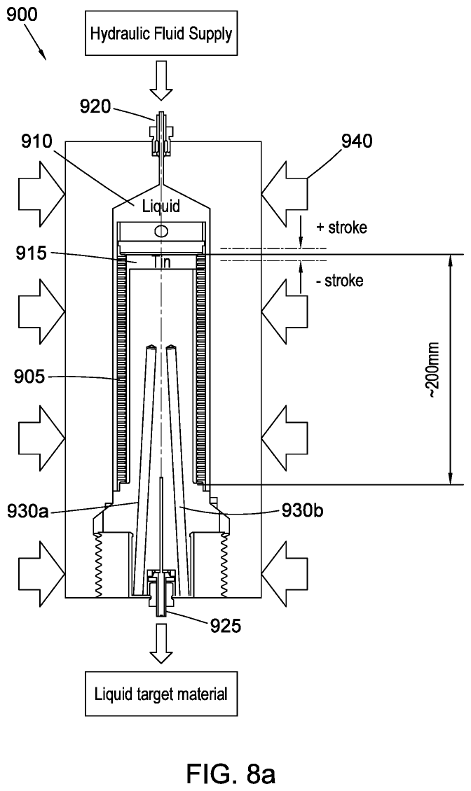

FIG. 7 schematically depicts an apparatus 800 according to another embodiment of the invention for supplying a liquid target material to a lithographic radiation source. The apparatus of FIG. 7 has features generally corresponding to the example embodiment of FIG. 5. As such, references numerals for common features are incremented by a factor of 200.

The apparatus 800 may be the apparatus 1112 of the fuel emitter 1111 in FIG. 2.

The apparatus 800 comprises a reservoir system including a first reservoir 810 configured to be connected to an ejection system via a transport system. The reservoir system further comprises a pressurizing system 820 to pressurize liquid target material in the first reservoir 810. The pressurizing system 820 is connected to the reservoir 810 via an inlet 811. The apparatus 800 comprises a separating device 840. The separating device 840 is configured to separate hydraulic fluid from the liquid target material in the first reservoir and to transfer a pressure from the hydraulic fluid to the liquid target material, as described in more detail below.

In the example embodiment, the separating device 840 is a deformable member 840 configured to deform under the pressure from the hydraulic fluid to vary a volume in the first reservoir for the hydraulic fluid. The separating device 840 is, for purposes of example, implemented as a bellows having a corrugated or concertinaed sidewall.

In the example apparatus, the pressurizing system 820 is configured to pressurize the hydraulic fluid around an exterior of the separating device 840, e.g. the bellows, within the first reservoir 810 to transfer the pressure from the hydraulic fluid to the liquid target material. In other example embodiments, the pressurizing system 820 may be configured to pressurize the hydraulic fluid inside the separating device 840, e.g. the bellows, within the first reservoir 810 to transfer the pressure from the hydraulic fluid to the liquid target material, such as described above with reference to the embodiments of FIGS. 3a and 3b.

The pressurizing system 820 further comprises vessel 821, which may act as a hydraulic fluid supply for filling and pressurizing a second reservoir 822 configured as a heating chamber. The vessel 821 may also act as a release and expansion tank in case of emergency.

The second reservoir 822 is in fluid communication with the inlet 811 of the first reservoir 810.

In some embodiments, the second reservoir 822 may be used to fill the first reservoir 810, e.g. via the tube between the second reservoir 822 and the inlet 811.

In use, once the second reservoir 822 is sufficiently filled using the fluid vessel 821 as a hydraulic fluid supply, a valve 823 between the vessel 821 and the second reservoir 822 may be closed. The second reservoir 822 may be used to heat the hydraulic fluid, which is preferably above the melting temperature of the target material in the separating device 840. The temperature of the hydraulic fluid in the second reservoir 822 may be used to accurately control the pressure in the hydraulic fluid. A pressure sensor 865 may be provided to sense a pressure of the hydraulic fluid. A control unit 870 may be provided to control the temperature of the hydraulic fluid inside the second reservoir 822 in dependency of a sensed actual pressure of the hydraulic fluid and a desired pressure of the hydraulic fluid.

More specifically, the hydraulic fluid may be selected such that, when a temperature of the hydraulic fluid and the second reservoir 822 is increased, a volumetric expansion of the hydraulic fluid exceeds a volumetric expansion of the second reservoir 822, thereby increasing a pressure of the hydraulic fluid.

As an example, in one embodiment a movable volume of less than 100 millimeters of hydraulic fluid/liquid target material may be foreseen. In embodiments, a maximum movable volume may be constrained by a size of the second reservoir 822 and the range of deformation of the separating device 840, e.g. an extent of expansion that the separating device 840 supports. Furthermore, a maximum temperature of the hydraulic fluid, e.g. due to a maximum temperature of a heater, may also limit movement and/or deformation of the separating device 840

An amount of expansion, and hence an amount of pressure generated by heating the hydraulic fluid in the second reservoir 822, may depend upon characteristics of the selected hydraulic fluid and characteristics of the second reservoir 822, as described below with reference to a non-limiting example.

In the non-limiting example, a temperature range in the second reservoir of 50C to 250C may be used for hydraulic fluid expansion. A volumetric thermal coefficient of expansion of a known hydraulic fluid maybe in the region of =0.0008/K=800 PPM/K. Therefore, when heating the hydraulic fluid from 50C to 250C, the hydraulic fluid may expand by 0.0008*200=0.16=16%.

When hydraulic fluid is compressed, e.g. due to an increased pressure caused by an increase in temperature in an enclosed volume, the hydraulic fluid may also reduce in volume to some extent. A compressibility of the known hydraulic fluid may be in the region of 5E-10 Pa-1. In other words, a bulk modulus, which is the inverse of compressibility, may be in the region of 2 GPa.

A target pressure may be in the region of 1400 bar=1.4E3*1E5=1.4E8 Pa. Under pressure the hydraulic fluid may compress by 1.4E8/2E9=7E-2=7%. Therefore, overall the volume of the hydraulic fluid may increase by approximately 16−7=9%.

A volumetric expansion of the second reservoir 822 also occurs due to the increase in temperature of the second reservoir 822. For example, for an assumed coefficient of thermal expansion (CTE) of 20 PPM in each of 3 dimensions, an expansion of the second reservoir due to an increase in temperature is in the region of 60 PPM/K.

Continuing with the above example, for an increase in temperature from 50 C to 250 C, a volume of the second reservoir may increase by approximately 60 PPM*200 K=1.2%.

Thus, overall a useable volume increase of the known hydraulic fluid due to a temperature increase of around 200K is: 16−7−1.2=approximately 7-8%.

That is, when a temperature of the known hydraulic fluid and the second reservoir 822 is increased, a volumetric expansion of the hydraulic fluid exceeds a volumetric expansion of the second reservoir 822, thereby increasing a pressure of the hydraulic fluid and providing a useable volume increase of the known hydraulic fluid for increasing a pressure of a liquid target material via a pressure transferred from the hydraulic fluid by the separating device 840.

Continuing with the above-described, non-limiting example, for the known hydraulic fluid, if the second reservoir is configured to hold 1 liter of the known hydraulic fluid, the second reservoir may expel in the region of 50-100 ml at 1400 bar pressure by increasing the temperature by 100-200 C.

In the example, the second reservoir 822 comprises an internal heating element 850 disposed in a volume defined by the second reservoir 822 and configured to be in direct contact with the hydraulic fluid held in the second reservoir 822.

In example embodiments, the internal heating element 850 may comprise a heating element or wire configured such that heating of the element or wire can be controlled, e.g. switched on and off rapidly, to allow for accurate pressure regulation. In an example, the internal heating element 850 may comprise a tungsten wire configured to be disposed in the hydraulic fluid in use. That is, by having the internal heating element 850 in direct contact with the hydraulic fluid, a fast temperature response may be achieved.

In the example, the second reservoir 822 also comprises an external heating and/or cooling element 855 configured to control a temperature of a sidewall of the second reservoir 822 for heating or cooling the hydraulic fluid held in the second reservoir.

In the example embodiment of FIG. 7, only an external cooling element 855 is depicted. However, in some examples either additional external heating elements may be implemented, or the external cooling element 855 may also be configurable as a heating element. To maintain thermal control of the second reservoir 822 in the event of a pressure decrease, it may be necessary to decrease a temperature of the second reservoir 822 using the external cooling element 855.

Also depicted in FIG. 7 is a vacuum connection 860 on the vessel 821. It is may be desirable that the vessel 860, which may act as a supply tank to the second reservoir 822, is filled without bubbles of gas, e.g. air, in the hydraulic fluid. This is because such bubbles would be highly compressible relative to a compressibility of the hydraulic fluid, and therefore may significantly influence an efficiency of the pressurization system 820.

In use, the vessel 821 may be filled via an inlet, such as the depicted return line 865, and the vacuum connection may be used to maintain a low pressure, such as in the region of 10 mbar in the vessel 821, thereby degassing the hydraulic fluid.

A drain tank 870 is also shown. The drain tank 870 may be connected through a valve 871 to the second reservoir 822. In case a rapid cooling of the second reservoir 822 is required, the hydraulic fluid from the second reservoir 822 may be flushed towards the drain tank 870. Fresh hydraulic fluid may be supplied to the second reservoir 822 taken from the vessel 821. In this way, a temperature of the second reservoir 822 can be rapidly reset. Furthermore, the described system is a closed system, thereby minimizing any chance for a hydraulic fluid spill and minimize any risk of contamination.

In some instances, it may be necessary to replace the hydraulic fluid. For example, elevated temperatures and/or pressures may cause the hydraulic fluid to degrade over time. The return line 865, together with the drain tank 870, may provide a hydraulic fluid refreshment system.

Hydraulic fluid may be removed from the first reservoir 810 and the second reservoir 822 and stored in the drain tank 870. Subsequently, new hydraulic fluid may be supplied from the vessel 821.

In use, the hydraulic fluid in the second reservoir 822 may be pre-pressurized. For example, a pressurized gas can be used to pre-pressurize the hydraulic fluid. As such, a pressure of the hydraulic fluid may be raised without raising the temperature of the second reservoir 822. This may advantageously enable a faster pressure increase by heating the second reservoir 822 at the beginning of a heating cycle. Furthermore, this may also advantageously lower a maximum heating temperature in the second reservoir 822.

In other embodiments, pre-pressurization may be implement by other means. For example, a hydraulic cylinder 721 arrangement as depicted in FIG. 6 may be used to pre-pressurize the hydraulic fluid in the second reservoir.

That is, in some examples, the hydraulic fluid in the second reservoir 822 may be pre-pressurized to a high pressure, such as approximately 1400 bar, using a course method, such as an the hydraulic cylinder 721 arrangement of FIG. 6. Subsequently, a fine regulation of the pressure of the hydraulic fluid during droplet generation may be controlled by controlling a temperature of the second reservoir 822.

An example method of use of the apparatus 800 is as follows.

For initial filling of the first reservoir 810 and the second reservoir 822 with hydraulic fluid, a valve 823 between the vessel 821 and the second reservoir is opened, allowing hydraulic fluid to fill the first reservoir 810 and the second reservoir 822. As described above, a controlled pressure may be used to de-gas the hydraulic fluid.

As also described above, in some embodiments pre-pressurization may take place, either through use of a pressurized gas or by a hydraulic cylinder arrangement.

The valve 823 is then closed and pressurization by heating the second reservoir 822 may commence. The hydraulic fluid in the first reservoir 810 separated from the liquid target material by the separating device 840 will also expand when heating of the first reservoir 810 commences, as described in more detail below.

In some examples, if pressure has to be quickly removed from the system, the valve 823 may be actuated to enable a flow of hydraulic fluid back into the vessel 821.

The vessel 821 may be pressurized by inert gas or may be kept vacuum.

When pressurization has to start again after a rapid vent, it may be desirable that the hydraulic fluid is cooled. As the hydraulic fluid cools, hydraulic fluid flows from the vessel 821 into the second reservoir 822. At the same time, hydraulic fluid in the first reservoir 810 may be topped-up, such that the system is reset to known volumes of hydraulic fluid. Then, the valve 823 is closed and the heating cycle can start.

In some examples, a passive pressure safety device such as a burst device (not shown) may be mounted close to the valve 823 to relieve pressure by allowing hydraulic fluid into the vessel 821 if, for example, a maximum allowable pressure is exceeded. In other examples, a relief valve may be implemented to reduce and/or remove the pressure.

Although FIGS. 5, 6 and 7 each only depict a single apparatus 600, 700, 800, a complete embodiment may comprise two apparatuses, as depicted in the example of FIG. 4. That is, embodiments may comprise a first apparatus 600, 700, 800 and a second apparatus 600, 700, 800, each corresponding to an apparatus of FIG. 5, 6 or 7 as described above, and each coupled in fluid communication to an ejection system by a transport system.

In some examples, the transport system may be configured to alternatingly supply liquid target material to the ejection system 1104 from the first apparatus 600, 700, 800 and the second apparatus 600, 700, 800. In some examples, the transport system may be configured to equalize a pressure in the first reservoir 610, 710, 810 of each of the first and the second apparatus 600, 700, 800 and to supply liquid target material to the ejection system 1104 from both the first apparatus and the second apparatus 600, 700, 800. That is, a first reservoir 610, 710, 810 of a first apparatus may be filled, after which a pressure in this first reservoir 610, 710, 810 may be equalized with a pressure in in a first reservoir 610, 710, 810 of a second apparatus 600, 700, 800, such that both apparatuses supply liquid target material for a while to the ejection system 1104. At some point, when the hydraulic fluid pressure level becomes low, and the first reservoir 610, 710, 810 of the first apparatus 600, 700, 800 prepares to take in and pressurize a new load of liquid target material. A pressure of this new load of liquid target material may subsequently equalized with the first reservoir 610, 710, 810 of the second apparatus 600, 700, 800, and so forth.

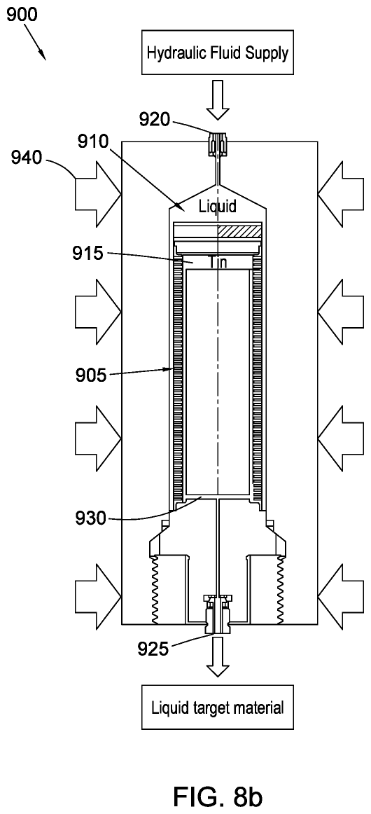

FIGS. 8a and 8b schematically depict cross-sectional views of an apparatus 900 according to another embodiment of the invention for supplying a liquid target material to a lithographic radiation source.

A volume within the apparatus 900 of FIGS. 8a (XZ cross-section) and 8b (YZ cross-section) defines a reservoir, which may correspond to the reservoir 610, 710, 810 of any of the above-described embodiments, e.g. in FIGS. 5, 6 and 7.

In the reservoir, a separating device 905 is provided as a bellow, e.g. a bellow comprising a deformable, corrugated sidewall.

The separating device 905 separates the hydraulic fluid 910 around an exterior of the separating device 905 from the liquid target material 915, e.g. tin, within the separating device 905.

An inlet 920 at an upper surface of the reservoir may be coupled to a second reservoir, e.g. the second reservoir 822 as depicted in FIG. 7, for supplying pressurized hydraulic fluid 910 to the apparatus 900.

An outlet 925 at a lower surface of the reservoir may be coupled to a transport system (not shown in FIGS. 8a and 8b), for providing liquid target material 915 to an ejection system 1104. In FIG. 8b, supply conduits 930 for carrying liquid target material 915 to the outlet 925 are depicted.

In an example, the reservoir is provided as a thick-walled stainless steel pressure vessel configured to withstand in excess of 1400bar pressure.

The example apparatus 900 comprises a pair of internal heating elements 930a, 930b disposed within the volume defined by the reservoir and configured to controllably apply heat to the volume defined by the reservoir. Although a pair of heating elements 930a, 930b are depicted, in other embodiments as few as a single heating element or more than two heating element may be implemented.

Each example heating element 930a, 930b is implemented as an elongate heating element extending away from a region of the outlet 925 of the reservoir.

The apparatus 900 also comprises at least one external heating element, represented by arrows 940, disposed outside the volume defined by the reservoir and configured to controllably apply heat to the reservoir. The at least one external heating element 940 may be configured to apply heat to different regions of the reservoir in a controlled sequence.

In use, when heating the apparatus 900 to an operating temperature, target material may melt to provide the liquid target material 915. In an example, the liquid target material 915 comprises tin, which may exhibit a 3% volumetric change at the transition from solid to liquid. Such a volumetric change may result in failure of the separating device 905 due to liquid tin entrapment, if the apparatus 900 is not heated in a controlled manner.

Therefore, in embodiments a controlled target material melting sequence may be implemented using the at least one external heating element 940 and the internal heating elements 930a, 930b.

In an example, the controlled target material melting sequence may start from the region of the outlet 925 towards a top side of the reservoir, and also radially from inside the separating device 905 towards outside the separating device 905.

Advantageously, such a controlled melting sequence, and in particular the provision on internal heating elements 930a, 930b to radially heat the target material from the inside to the outside of the reservoir may prevent occurrence of liquid tin entrapment.

Further advantages of the combined internal and external heating concept include: use of a lower mean fluid temperature increasing hydraulic fluid service life; a decreased overall temperature of the reservoir; design freedom in applicable materials, e.g. use of O-rings instead of metal seals; increased material strength, since yield and ultimate tensile strength may deteriorate with temperature; and protection of the reservoir material from contact with aggressive liquid target material in the event of liquid target material leaks.

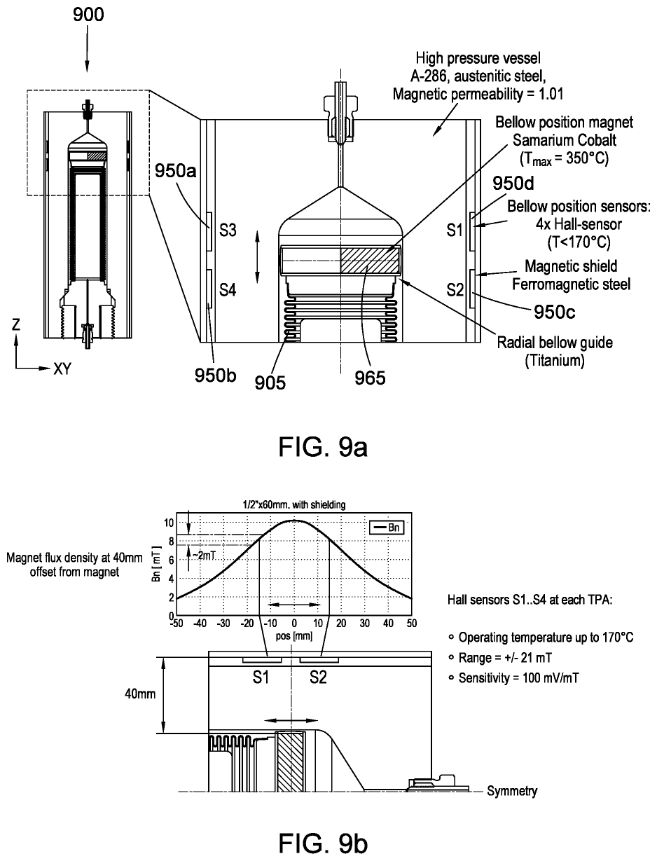

As depicted in FIGS. 9a and 9b, the apparatus 900 may comprise at least one sensor 950a-d configured to sense a displacement of the separating device 905 within the reservoir.

In an example, a contactless sensor 950a-d such as Hall sensor may be implemented. The sensor 950a-d may be configured to detect a displacement of the separating device 905 by sensing a magnetic field from one or more magnets 965 propagating through a sidewall of the reservoir.

FIG. 9b depicts an example of a simulation of magnet flux at the contactless sensor position relative to a displacement of the separating device 905. It can be seen in FIG. 9b that a sensed magnetic flux density measurably varies between a first Hall sensor S1 and a second Hall sensor S2. That is, in the depicted example embodiment with the Hall sensors S1 and S2 at a distance of approximately 40 millimeters from the one or more magnets 965, a variation in magnetic flux density sensed by sensors S1 and S2 corresponds to a displacement of the one or more magnets 965 relative to the sensors S1 and S2. In a non-limiting example, a resolution in the displacement of the one or more magnets 965 in the region of 10 micrometers may be obtained, which may equate to a variation in volume of approximately 0.02 ml of liquid target material.

Although as few as a single sensor may be implemented, in the example of FIG. 9a four sensors 950a, 950b, 950c, 950d are implemented. This may beneficially enable detection of unwanted deformation, e.g. tilting or non-uniform deformation of the separating device. This may also beneficially provide redundancy in the event of a sensor failure.

In an example, processing means (not shown) may be coupled to the at least one sensor 950a-d and configured to determine, based on a sensed displacement of the separating device 905: a level of liquid target material 915 in the reservoir; that a displacement of the separating device 905 has exceeded an upper or lower threshold; and/or a displacement of the separating device 905 has deviated from an expected value. This may be beneficial in the detection of a failure of the separating device 905, wherein liquid target material 915 and/or hydraulic fluid 910 may be able to leak through a point of failure of the separating device 905, potentially damaging sidewalls of the reservoir and/or affecting operation of the ejection system 1104 and radiation generation.

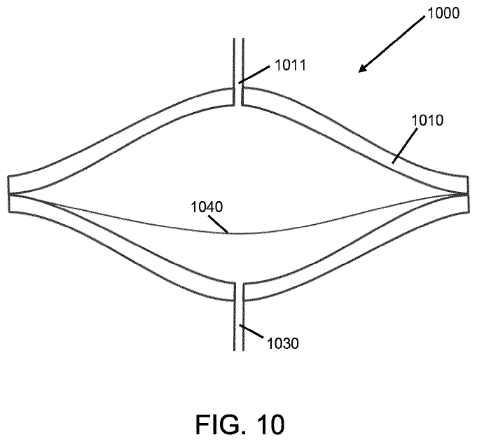

FIG. 10 schematically depicts an apparatus 1000 according to yet another embodiment of the invention for supplying a liquid target material to a lithographic radiation source. The apparatus 1000 may be the apparatus 1112 of the fuel emitter 1111 in FIG. 2.

The apparatus 1000 includes a reservoir system with a reservoir 1010 having an inlet 1011 for hydraulic fluid and an outlet 1040 for liquid target material. The hydraulic fluid and the liquid target material are separated from each other using a deformable member including a membrane 1040. An advantage thereof is that the volume for the hydraulic fluid and the volume for the liquid target material are variable without the two media touching each other. The deformability, e.g. caused by flexibility and/or elasticity, of the membrane 1040 allows to adapt to each combination of volumes thereby allowing the hydraulic fluid to apply pressure to the liquid target material to supply the pressurized liquid target material to an ejection system. The membrane is preferably non-permeable for the hydraulic fluid and/or the target material.

Although some of the above described embodiments include a bellows, the deformable member may alternatively be formed as a bladder or balloon.

The pressure applied to the liquid target material by the pressurizing system in the above embodiments may be at least 300 bar, preferably at least 400 bar, more preferably at least 500 bar, even more preferably at least 600 bar, for instance at least 700 bar, at least 900 bar, at least 1100 bar, or at least 1300 bar.

Although not specified above, the hydraulic fluid may be any suitable hydraulic fluid, for instance water (which is liquid above 40 bars of pressure and a temperature of 260 degrees), glycols, sebacate oils, such as bis(2-ethylhexyl) sebacate, or perfluoropolyether (PFPE) oils, such as Galden HT).

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

### CLAUSES

1. An apparatus for supplying a liquid target material to a radiation source, comprising a reservoir system including a reservoir configured to be connected to an ejection system and a pressurizing system to pressurize liquid target material in the reservoir, wherein the pressurizing system comprises a separating device such as a deformable member configured to transfer pressure from a pressure fluid, e.g. a hydraulic fluid, to the liquid target material, and configured to form a variable volume in the reservoir for the liquid target material and the pressure fluid.
2. An apparatus according to clause 1, wherein the pressurizing system is configured to apply a pressure of at least 300 bar, preferably at least 700 bar, more preferably at least 900 bar, even more preferably at least 1100 bar, and most preferably at least 1300 bar.
3. An apparatus according to clause 1 or 2, wherein the deformable member comprises a membrane.
4. An apparatus according to clause 1 or 2, wherein the deformable member comprises a bellows.
5. An apparatus according to clause 4, wherein the bellows is configured to hold the pressure fluid inside the bellows.
6. An apparatus according to clause 4, wherein the bellows is configured to hold the liquid target material inside the bellows.
7. An apparatus according to any of clauses 4-6, wherein the bellows has a tubular shape with a closed end, an open end, and a deformable side wall extending between the closed end and the open end.
8. An apparatus according to clause 7, wherein the deformable member further includes a rigid member forming the closed end of the bellows.
9. An apparatus according to clause 8, wherein the rigid member provides a barrier between the pressure fluid and a second pressure fluid, e.g. a gas, of the pressurizing system, wherein the pressurizing system is configured to apply the second pressure fluid to the rigid member to deform the bellows and to apply the pressure fluid to the deformable side wall to provide a counter-pressure.
10. An apparatus according to clause 9, wherein the pressurizing system comprises a pressure regulating system configured to maintain a pressure in the pressure fluid substantially equal to the pressure in the liquid target material.
11. An apparatus according to any of clauses 7-10, wherein the pressurizing system comprises a sensor to determine a position of the closed end of the bellows in the reservoir.
12. An apparatus according to any of clauses 1-11, wherein the reservoir system further comprises a heating system to heat the reservoir.
13. An apparatus according to clause 12, wherein the pressure fluid and at least a part of the deformable member are configured to conduct heat generated by the heating system to the liquid target material.
14. An apparatus according to any of clauses 1-13, wherein the reservoir comprises one or more guiding elements to guide deformation of the deformable member in the reservoir.
15. An apparatus according to any of clauses 1-8, wherein the pressurizing system is configured to apply the pressure fluid to the deformable member.
16. An apparatus according to any of clauses 1-15, wherein the reservoir comprises a wall portion with a connector part to be connected to the ejection system or a pressure fluid supply system.
17. An apparatus according to clause 16, wherein the wall portion is connected to the reservoir using a screw connection.
18. An apparatus according to the combination of clause 4 and clause 16 or 17, wherein the connector part is part of the bellows and extends in or through an opening in the wall portion.
19. An apparatus according to the combination of clause 7 and clause 18, wherein the connector part is arranged at the open end of the bellows, and wherein the bellows is connected to the wall portion with its open end, such that the medium inside the bellows does not come into contact with the reservoir.
20. An apparatus according to any of clauses 1-19, wherein the deformable member comprises one or more of the following materials: polyimide, polytetrafluoroethylene, tungsten, tantalum, Molybdenum.
21. An apparatus according to any of clauses 1-20, wherein the reservoir system is a first reservoir system, and wherein the apparatus further comprises a similar second reservoir system configured to be connected to the ejection system in series with the first reservoir system.
22. An apparatus according to any of clauses 1-20, wherein the reservoir system is a first reservoir system, and wherein the apparatus further comprises a similar second reservoir system configured to be connected to the ejection system in parallel with the first reservoir system.
23. An apparatus according to any of clauses 1-22, wherein the target material is tin.
24. An apparatus according to any of clauses 1-23, further comprising a priming system configured to receive a solid matter that includes the target material, and a transport system that extends from the priming system to the reservoir system, the transport system configured to provide a flow path for the target material between the priming system and the reservoir system.
25. An apparatus according to clause 24, wherein the transport system further comprises a regulation apparatus configured to control a flow of target material from the priming system.
26. A fuel emitter comprising an apparatus according to any of clauses 1-25 and an ejection system.
27. A fuel emitter according to clause 26, wherein the ejection system is configured to eject a stream of droplets to a plasma formation location.
28. A fuel emitter according to clause 27, further comprising a droplet monitoring device to monitor the stream of droplets.
29. A fuel emitter according to clause 28, further comprising a control unit arranged between the droplet monitoring device and the pressurizing system to adjust a pressure applied by the pressurizing system to the liquid target material in the reservoir based on an output of the droplet monitoring device.
30. A fuel emitter according to clause 28, further comprising a control unit arranged between the droplet monitoring device and the ejection system to adjust operation of the ejection system based on an output of the droplet monitoring device.
31. A radiation source for a lithographic tool comprising a fuel emitter according to any of clauses 26-30.
32. A radiation source according to claim 31, wherein the radiation source is configured to output EUV radiation.
33. A radiation source according to clause 31 or 32, wherein the radiation source is a laser produced plasma source.
34. A lithographic apparatus comprising a radiation source according to any of clauses 31-33.
35. A method for supplying liquid target material to a radiation source, wherein liquid target material in a reservoir is pressurized by pressurizing a deformable member using a pressure fluid, said deformable member transferring pressure from the pressure fluid to the liquid target material, and wherein the liquid target material is supplied from or to the reservoir by varying a volume for the liquid target material made possible by the deformable member.
36. A method according to clause 35, wherein the liquid target material is pressurized to a pressure of at least 300 bar, preferably at least 700 bar, more preferably at least 900 bar, even more preferably at least 1100 bar, and most preferably at least 1300 bar.

1-17. (canceled)

18. An apparatus for supplying a liquid target material to a radiation source, comprising:
a first reservoir;
a pressurizing system configured to pressurize a hydraulic fluid; and
a separating device configured to separate the hydraulic fluid from the liquid target material in the first reservoir and to transfer a pressure from the hydraulic fluid to the liquid target material.

19. The apparatus according to claim 18, wherein the separating device comprises a deformable member configured to deform under the pressure from the hydraulic fluid to vary a volume of the first reservoir, and wherein the separating device comprises at least one of: polyimide, polytetrafluoroethylene, tungsten, tantalum, Molybdenum.

20. The apparatus of claim 18, wherein the separating device comprises a bellows having a corrugated or concertinaed sidewall, and wherein the pressurizing system is configured to pressurize the hydraulic fluid inside the bellows or around an exterior of the bellows within the reservoir to transfer the pressure from the hydraulic fluid to the liquid target material.

21. The apparatus of claim 18, comprising at least one external heating element disposed outside a volume defined by the first reservoir and configured to controllably apply heat to the first reservoir, and wherein the at least one external heating element is configured to apply heat to different regions of the first reservoir in a controlled sequence.

22. The apparatus of claim 18, comprising at least one internal heating element disposed within the volume defined by the first reservoir and configured to controllably apply heat to the volume defined by the first reservoir, and wherein the at least one internal heating element comprise at least one elongate heating element extending away from an inlet/outlet region of the first reservoir.

23. The apparatus of claim 18, comprising:
at least one sensor configured to sense a displacement of the separating device within the first reservoir; and
a processor coupled to the at least one sensor and configured to determine, based on a sensed displacement of the separating device:
a level of liquid target material in the first reservoir;
a displacement of the separating device has exceeded an upper or lower threshold; and/or
a displacement of the separating device has deviated from an expected value.

24. The apparatus of claim 18, wherein the pressurizing system comprises a second reservoir configured to hold the hydraulic fluid and for fluid communication with the first reservoir to supply the hydraulic fluid to the first reservoir, and wherein the second reservoir is configured as a heating chamber configured to apply heat to the hydraulic fluid.

25. The apparatus of claim 24, comprising at least one of:
an internal heating element disposed in a volume defined by the second reservoir and configured to be in direct contact with the hydraulic fluid held in the second reservoir; and/or
an external heating and/or cooling element configured to control a temperature of a sidewall of the second reservoir for heating or cooling the hydraulic fluid held in the second reservoir.

26. The apparatus of claim 24, comprising a vessel configured to be in fluid communication with the second reservoir and configured to supply hydraulic fluid to the second reservoir, wherein:
the vessel is configured to be disposed above the second reservoir such that gravity induces a flow of hydraulic fluid from the vessel to the second reservoir; or
the vessel comprises a hydraulic cylinder for pre-pressurizing the hydraulic fluid.

27. The apparatus of claim 26, wherein the vessel comprises an inlet and the pressurizing system is configured to provide a pressurized fluid to the inlet to pre-pressurize the hydraulic fluid in the vessel.

28. The apparatus of claim 18, wherein the hydraulic fluid is selected such that, when a temperature of the hydraulic fluid and the second reservoir is increased, a volumetric expansion of the hydraulic fluid exceeds a volumetric expansion of the second reservoir.

29. A fuel emitter for supplying a liquid target material to a radiation source, the system comprising:
a first apparatus according to claim 18;
a second apparatus according to claim 18; and
wherein the first apparatus and the second apparatus are coupled in fluid communication to
an ejection system by a transport system.

30. A radiation source for a lithographic tool comprising a fuel emitter of claim 29, wherein the radiation source is configured to output EUV radiation.

31. A lithographic tool comprising a radiation source of claim 30.

32. A method of manufacturing integrated circuits comprising the step of supplying liquid target material to a radiation source, wherein liquid target material in a first reservoir is pressurized by pressurizing a hydraulic fluid separated from the liquid target material in the first reservoir by a separating device configured to transfer a pressure from the hydraulic fluid to the liquid target material.
